(19) United States
(12) Patent Application Publication
(10) Pub. No.: US 2024/0154467 A1
(43) Pub. Date: May 9, 2024

(54) SHIELDING MODULE FOR WIRELESS CHARGING AND WIRELESS CHARGING APPARATUS

(71) Applicant: Lanto Electronic Limited, Kunshan City (CN)

(72) Inventors: Hui ZHANG, Kunshan City (CN); Yi ZHOU, Kunshan City (CN); Yanlei YANG, Kunshan City (CN); Junyun ZHANG, Kunshan City (CN)

(73) Assignee: Lanto Electronic Limited, Kunshan City (CN)

(21) Appl. No.: 18/106,780

(22) Filed: Feb. 7, 2023

(30) Foreign Application Priority Data
Nov. 3, 2022 (CN) 202222924724.8

(51) Int. Cl. H02J 50/70; H05K 9/00

(52) U.S. Cl. CPC H02J 50/70; H05K 9/0084

(57) ABSTRACT

Provided are a shielding module for wireless charging and a wireless charging apparatus, which belong to the field of wireless charging technology. The shielding module for wireless charging includes a tray, a plurality of ferrites and a colloid, where the tray has a bottom wall and an annular sidewall connected to an edge of the bottom wall, the sidewall and the bottom wall form an accommodation groove therebetween, the plurality of ferrites are arranged in the accommodation groove and completely accommodated in the accommodation groove, the colloid is filled in the accommodation groove in a potting manner and filled between the ferrites and the bottom wall, and the tray and the ferrites are integrally formed through the colloid.

### CROSS-REFERENCE TO RELATED APPLICATION(S)

This application claims priority to Chinese Patent Application No. 202222924724.8 filed Nov. 3, 2022, the disclosure of which is incorporated herein by reference in its entirety.

### TECHNICAL FIELD

The present utility model relates to the field of wireless charging technology and, in particular, to a shielding module for wireless charging and a wireless charging apparatus.

### BACKGROUND

In recent years, new energy vehicles have developed rapidly. In the wireless charging system for new energy vehicles, the vehicle-mounted wireless charger, as an important component of the system, receives the magnetic field energy and converts the magnetic field energy into the direct current that can be used to charge the vehicle battery system.

At present, the vehicle-mounted wireless charging system usually includes a vehicle-mounted shielding plate, a metal upper cover, a ferrite shielding plate, a magnetic field receiving coil and a coil tray which are arranged from top to bottom sequentially. In addition, the ferrite shielding plate is usually formed by splicing multiple ferrites in the form of small pieces so that the area of the formed ferrite shielding plate is sufficient to cover the edge of the magnetic field receiving coil. Since the ferrite shielding plate is in an alternating magnetic field, the magnetic field forms an induced electromotive force inside the ferrites and generates an internal eddy current, causing the ferrites to generate heat severely. Therefore, the use of ferrites in the form of small pieces can reduce the eddy current and decrease the generated heat. However, there is a problem that multiple ferrites in the form of small pieces are difficult to install.

In the related art, the front surface and the back surface of multiple ferrites are bonded to each other using plastic film sheets backed with an adhesive. However, such a manner cannot achieve the mutual isolation between ferrites, and the mutual friction between ferrites causes the phenomena of slagging and broken corners, affecting the performance and the service life of the ferrite and resulting in the poor capability of the ferrite to resist the mechanical damage.

### SUMMARY

The object of the present utility model is to provide a shielding module for wireless charging and a wireless charging apparatus.

Based on the preceding conception, the technical solutions adopted by the present utility model are as follows.

A shielding module for wireless charging is provided. The shielding module for wireless charging includes a tray, multiple ferrites and a colloid. The tray has a bottom wall and an annular sidewall connected to an edge of the bottom wall, the sidewall and the bottom wall form an accommodation groove therebetween. The multiple ferrites are arranged in the accommodation groove and completely accommodated in the accommodation groove. The colloid is filled in the accommodation groove in a potting manner and filled between the ferrites and the bottom wall, and the tray and the ferrites are integrally formed through the colloid.

Optionally, the bottom wall is provided with multiple support blocks on the surface of the bottom wall facing the accommodation groove, the ferrites are supported on the support blocks, and the colloid is arranged to avoid the support blocks.

Optionally, the support blocks are provided, and each ferrite is supported on at least one support block.

Optionally, the support blocks include multiple first support blocks and multiple second support blocks, the first support blocks are arranged in the middle portion of the accommodation groove, and the second support blocks are uniformly spaced at the edge of the bottom wall along the circumferential direction of the tray.

Optionally, the shielding module for wireless charging further includes an adhesive film. The top surfaces and/or the bottom surfaces of the ferrites are adhered to the adhesive film, and the adhesive film is bonded to the colloid.

Optionally, the colloid is filled between the multiple ferrites and the sidewall.

Optionally, a boss is arranged in the middle portion of the tray, and the boss is provided with a through hole penetrating the upper side and the lower side of the boss. The ferrites are directly in contact with the boss or the colloid is filled between the boss and the ferrites.

Optionally, the colloid is a thermally conductive colloid, and the tray is a thermally conductive plastic.

Optionally, the colloid covers the top surfaces of the ferrites, and the top surface of the colloid is flush with the top surface of the tray.

A wireless charging apparatus is provided. The wireless charging apparatus includes a plastic housing, a coil assembly arranged on the plastic housing, a heat dissipation housing arranged on the coil assembly, a metal upper cover arranged on the heat dissipation housing and the preceding shield module for wireless charging, where the shield module for wireless charging is arranged on the side of the heat dissipation housing facing the coil assembly.

### BRIEF DESCRIPTION OF DRAWINGS

FIG. 1 is a structure view of a shielding module for wireless charging according to an embodiment of the present utility model;

FIG. 2 is an exploded view of a shielding module for wireless charging according to an embodiment of the present utility model;

FIG. 3 is a structure view of a tray according to an embodiment of the present utility model;

FIG. 4 is a sectional view of a shielding module for wireless charging according to an embodiment of the present utility model;

FIG. 5 is an enlarged view of position A shown in FIG. 4 according to the present utility model;

FIG. 6 is another sectional view of a shielding module for wireless charging according to an embodiment of the present utility model;

FIG. 7 is an enlarged view of position B shown in FIG. 6 according to the present utility model;

FIG. 8 is a structure view of a wireless charging apparatus according to an embodiment of the present utility model;

FIG. 9 is an exploded view one of a wireless charging apparatus according to an embodiment of the present utility model; and

FIG. 10 is an exploded view two of a wireless charging apparatus according to an embodiment of the present utility model.

### REFERENCE LIST

1 tray
11 accommodation groove
12 support block
121 first support block
122 second support block
13 boss
131 through hole
14 first notch
15 bottom wall
16 sidewall
2 ferrite
21 second notch
3 colloid
10 plastic housing
20 coil assembly
30 heat dissipation housing
40 metal upper cover

### DETAILED DESCRIPTION

To better illustrate the solved problem, adopted solutions and achieved effects of the present utility model, the present utility model is further described in conjunction with drawings and embodiments. It is to be understood that the embodiments set forth below are intended to merely illustrate and not to limit the present utility model. Additionally, it is to be noted that for ease of description, only a part, not all, related to the present utility model is illustrated in the drawings.

In the description of the present utility model, unless otherwise expressly specified and limited, the term “connected to each other”, “connected” or “secured” is to be construed in a broad sense, for example, as securely connected, detachably connected or integrated; mechanically connected or electrically connected; directly connected to each other or indirectly connected to each other via an intermediary; or internally connected between two components or interaction relations between two components. For those of ordinary skill in the art, specific meanings of the preceding terms in the present utility model may be understood based on specific situations.

In embodiments of the present utility model, unless otherwise expressly specified and limited, when a first feature is described as “on” or “below” a second feature, the first feature and the second feature may be in direct contact or may be in contact via another feature between the two features instead of being in direct contact. Moreover, when the first feature is described as “on”, “above” or “over” the second feature, the first feature is right on, above or over the second feature, the first feature is obliquely on, above or over the second feature, or the first feature is simply at a higher level than the second feature. When the first feature is described as “under”, “below” or “underneath” the second feature, the first feature is right under, below or underneath the second feature, the first feature is obliquely under, below or underneath the second feature, or the first feature is simply at a lower level than the second feature.

In the description of the embodiments of the present utility model, orientations or position relations indicated by terms such as “upper”, “lower” and “right” are based on orientations or position relations shown in the drawings. These orientations or position relations are intended only to facilitate description and simplify operations and not to indicate or imply that an apparatus or element referred to must have such specific orientations or must be configured or operated in such specific orientations. Thus, these orientations or position relations are not to be construed as limiting the present utility model. In addition, the terms “first” and “second” are used to distinguish between descriptions and have no special meaning.

The present utility mode provides a shielding module for wireless charging to prevent the ferrites from rubbing with each other and avoid the phenomena of slagging and broken corners of the ferrites, thereby ensuring the performance and the service life of the ferrite and improving the capability of the ferrite to resist mechanical damage. The shielding module for wireless charging is applied to a wireless charging apparatus, and the wireless charging apparatus may be a wireless charging apparatus of the new energy vehicle.

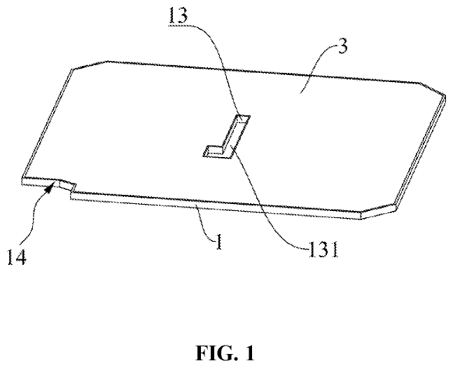

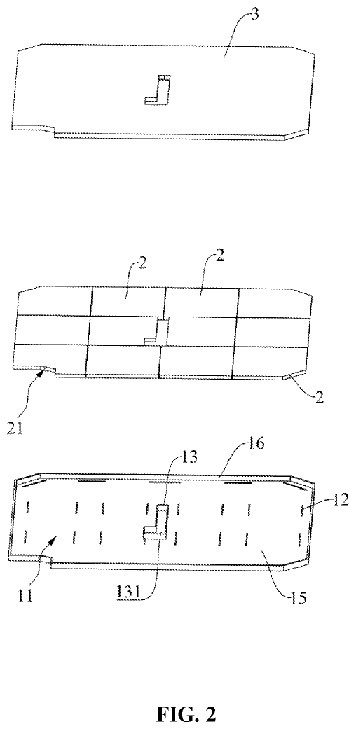

As shown in FIGS. 1 and 2, the shielding module for wireless charging includes a tray 1, ferrites 2 in a same horizontal plane and a colloid 3. The tray 1 has a bottom wall 15 and a sidewall 16 connected to the edge of the bottom wall 15, that is, the tray 1 has a plate-like structure having the sidewall 16. In some embodiments, the sidewall 16 is connected perpendicularly to the bottom wall 15. The sidewall 16 is annular and circumferentially arranged along the circumferential direction of the bottom wall 15, and the sidewall 16 and the bottom wall 15 form an accommodation groove 11 therebetween.

The ferrite 2 is an important functional element and plays a role in magnetic circuit guidance and magnetic shielding. In the present utility model, multiple ferrites 2 are provided, the multiple ferrites 2 are arranged in the accommodation groove 11, and each ferrite 2 is completely accommodated in the accommodation groove 11, that is, the ferrite 2 is not exposed out of the accommodation groove 11 of the tray 1. In some embodiments, the multiple ferrites 2 are arranged in the accommodation groove 11 in an array, and it is to be understood that the multiple ferrites 2 may also be arranged in the accommodation groove 11 along the length direction or the width direction of the tray 1. The size of each ferrite 2 is the same or different, and the multiple ferrites 2 need to fill the accommodation groove 11 as much as possible. The depth of the accommodation groove 11 is larger than the thickness of each ferrite 2 so that when the ferrites 2 are arranged in the accommodation groove 11, a space exists between the top surface of each ferrite 2 and the notch of the accommodation groove 11.

The colloid 3 is filled in the accommodation groove 11 in a potting manner, that is, when the colloid 3 needs forming, the colloid 3 in a liquid state is poured into the accommodation groove 11 in which the ferrites 2 are arranged, and after a period of time, the colloid 3 in a liquid state solidifies to form the colloid 3. The colloid 3 is filled between the bottom wall 15 and the ferrites 2 and between the adjacent ferrites 2 and can seal the gap between the bottom wall 15 and the ferrites 2. The tray 1 and multiple ferrites 2 are integrally formed through the colloid and remain relatively fixed. That is, the shielding module for wireless charging in the present utility model has an integral structure, and in other words, the shielding module for wireless charging has an integral structure.

In the shielding module for wireless charging provided by the present utility model, the tray 1 is provided, multiple ferrites 2 are arranged in the accommodation groove 11 of the tray 1, and the colloid 3 is filled between the ferrites 2 and the bottom wall so that each ferrite 2 can be fixed on the tray 1 by the colloid 3. In this manner, the ferrites 2 can be prevented from rubbing with each other, and the phenomena of slagging and broken corners of the ferrites 2 can be avoided, thereby ensuring the performance and the service life of the ferrite 2, improving the capability of the ferrite 2 to resist mechanical damage, improving the integrality of the shielding module for wireless charging, and enhancing the capability of the shielding module for wireless charging to resist mechanical damage.

Optionally, the gap between the ferrites 2 may be filled with the colloid 3, which is not limited to the present utility model.

In the present utility model, the use of the tray 1 is such that the multiple ferrites 2 form the entire shielding module for wireless charging, and the sidewall 16 of the tray 1 can protect the periphery of the ferrites 2.

Optionally, the colloid 3 is a thermally conductive colloid capable of transferring the heat generated by the ferrites 2 or the heat generated by the coil assembly under the shielding module for wireless charging to the cooling circuit above the shielding module for wireless charging. The colloid 3 is filled between the ferrites 2 and filled on the upper surface of the ferrites 2 so that heat can be conducted away through the thermally conductive colloid.

In some embodiments, the colloid 3 may also cover the upper surface of the multiple ferrites 2. As shown in FIG. 4 or FIG. 5, the heat generated by the coil assembly can be transferred to the cooling circuit through the colloid 3 between the ferrites 2 and the bottom wall of the accommodation groove 11, the colloid 3 between the ferrites 2 and the colloid 3 on the upper surface of the ferrites 2, thereby increasing the heat dissipation capability.

In some embodiments, the colloid 3 is a glue with good thermal conductivity, such as thermally conductive silica gel, a thermally conductive rubber and the like. Optionally, with continued reference with FIG. 5, the colloid 3 is filled between the side wall of the ferrites 2 at the edge of the tray 1 and the sidewall 16, that is, the colloid 3 is filled between the sidewall 16 and the ferrites 2, thereby further improving the heat transfer effect of the shielding module for wireless charging.

Further, in order to further improve the heat transfer effect of the shielding module for wireless charging, the tray 1 is a thermally conductive plastic to obtain a better heat transfer effect. In the present utility model, the tray 1 is made of an engineering plastic, specifically the nylon-bonded fiberglass composite, and the molding process for the mass production of the tray is injection molding so that the tray 1 has both functions of conducting heat conduction and limiting the ferrite 2.

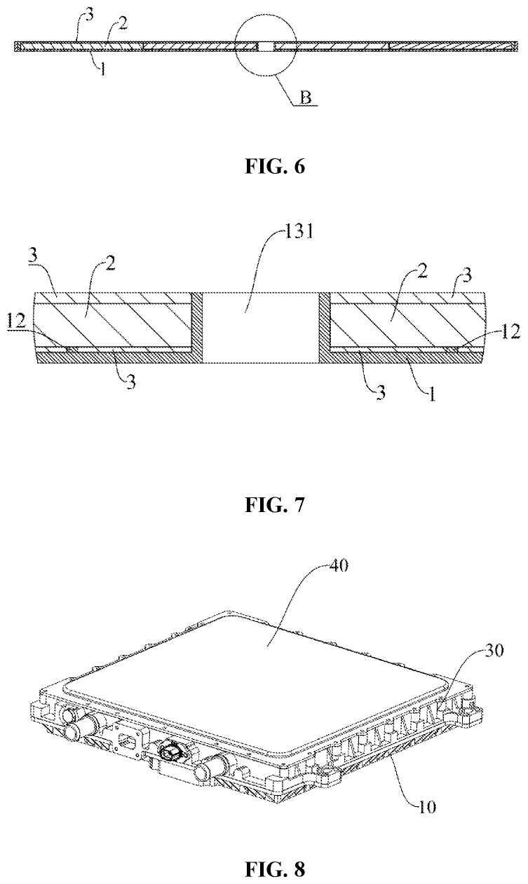

Optionally, with continued reference to FIG. 2, the bottom wall 15 is provided with support blocks 12 on the surface of the bottom wall 15 facing the accommodation groove 11, multiple ferrites 2 are supported on the support blocks 12, and the colloid 3 is arranged to avoid the support blocks 12. In some embodiments, multiple support blocks 12 are provided, and each ferrite 2 is supported on at least one support block 12. The support blocks 12 support the ferrites 2, as shown in FIGS. 6 and 7, so that the colloid 3 can be easily formed between the bottom wall of the ferrites 2 and the bottom wall 15 of the tray 1. In the present utility model, the support block 12 is in a striped shape to obtain a smaller volume on the premise of having a better support effect.

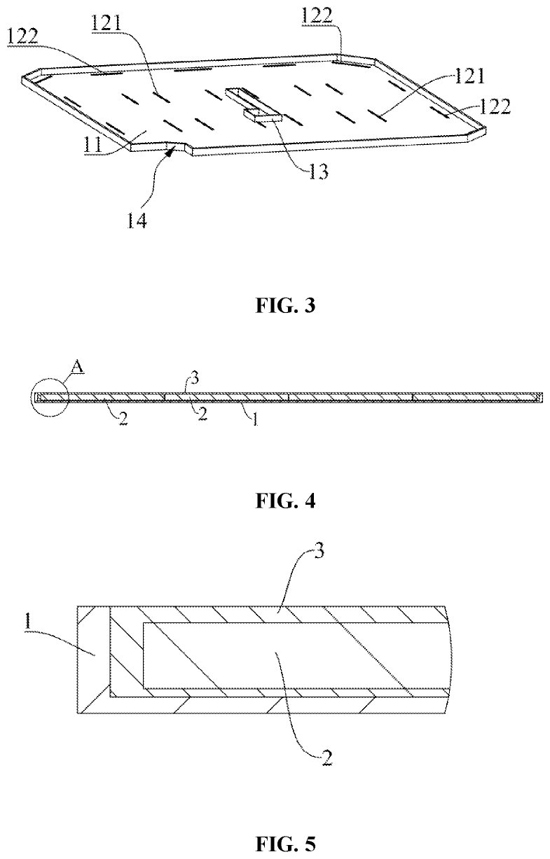

As shown in FIG. 3, the multiple support blocks 12 include multiple first support blocks 121 and multiple second support blocks 122. The multiple first support blocks 121 are arranged in the middle portion of the accommodation groove 11, and the multiple second support blocks 122 are arranged in the periphery of the multiple first support blocks 12, that is, the multiple second support blocks 122 are uniformly spaced at the edge of the bottom wall 15 of the tray 1 along the circumferential direction of the tray 1. The first support blocks 121 and the second support block 122 are arranged in the preceding manner so that when the colloid 3 in a liquid state is poured into the accommodation groove 11, the colloid 3 smoothly flows between the ferrites 2 and the bottom wall 15 and completely fills the gap between the bottom wall 15 and the ferrites 2, thereby ensuring the heat transfer effect.

In the present utility model, with reference to FIGS. 3 and 7, a boss 13 is arranged in the middle portion of the tray 1, and specifically, the boss 13 is arranged at the center of the accommodation groove 11. The boss 13 is provided with a through hole 131 penetrating the upper side and the lower side of the boss 13, and the through hole 131 is used for allowing a connector of the coil assembly to pass through. With the arrangement of the boss 13, the opening area in the middle of the ferrites 2 can be protected from deformation. In some embodiments, as shown in FIG. 7, the ferrites 2 close to the boss 13 are in direct contact with the boss 13, that is, no colloid 3 exists between the boss 13 and the ferrites 2. In other embodiments, the colloid 3 is filled between the boss 13 and the ferrites 2 so that the ferrites 2 are not in direct contact with the boss 13, preventing the ferrites 2 from being rubbed and damaged by the boss 13.

In the present utility model, the height of the boss 13 is the same as the thickness of the tray 1, that is, the boss 13 does not protrude out of the notch of the accommodation groove 11.

With reference to FIGS. 1 to 3, the tray 1 has a polyprism shape, and in the present utility model, the tray 1 has an octagonal prism shape. One side of the tray 1 has one first notch 14, and the first notch 14 is sued for allowing the other connector of the coil assembly to pass through, that is, the first notch 14 is used for avoiding the other connector of the coil assembly. One ferrite 2 among the multiple ferrites 2 has a second notch 21 matching the first notch 14 in both shape and size, and the ferrite 2 is located at a position where the tray 1 has the first notch 14.

In the present utility model, as shown in FIG. 5, the colloid 3 covers the top surfaces of the multiple ferrites 2 so that no ferrite 2 is exposed out of the colloid 3. The top surface of the colloid 3 is flush with the top surface of the tray 1 so that the arrangement of the colloid 3 does not additionally increase the thickness of the shielding module for wireless charging. In this manner, the thickness of the shielding module for wireless charging is small so that the shielding module for wireless charging can be better applied to the wireless charging apparatus with high thickness requirements.

In some embodiments, the shielding module for wireless charging may further include an adhesive film. The top surfaces of the multiple ferrites are adhered to the adhesive film to improve the integrality of the multiple ferrites 2, and the adhesive film is bonded to the colloid 3 located on the top of the multiple ferrites 2. In the present utility model, the ferrites are first bonded to the adhesive film, and the adhesive film is bonded to the colloid 3. In other embodiments, the bottom surfaces of the multiple ferrites 2 are adhered to the adhesive film, and at this point, the ferrites 2 are first bonded to the adhesive film, and the adhesive film is bonded to the colloid 3 located on the bottom wall 15 so that the ferrites 2 obtain better integrality; or the top surface and the bottom surface of the multiple ferrites 2 are adhered to one layer of adhesive film, respectively so that the ferrites 2 obtain better integrality, thereby preventing the ferrites 2 from being loose. In the present utility model, the adhesive film may be a plastic film, a release film and the like, which is not limited to the present utility model. It is to be noted that the adhesive film can be fixed in the accommodation groove 11 of the tray 1 by the colloid 3 so that the tray 1, the ferrites 2 and the adhesive film are integrally formed through the colloid 3.

In the present utility model, the colloid 3 may further seal the gap between the multiple ferrite 2, that is, adjacent ferrites 2 have no gap but are filled with the colloid 3 to further prevent two adjacent ferrites 2 from colliding and rubbing with each other. Since the surrounding of each ferrite 2 is filled with the colloid 3, the ferrites 2 can be prevented from rubbing with each other, and the phenomena of slagging and broken corners of the ferrites 2 can be avoided, thereby ensuring the performance and the service life of the ferrite 2, improving the capability of the ferrite 2 to resist mechanical damage, improving the integrality of the shielding module for wireless charging, and enhancing the capability of the shielding module for wireless charging to resist mechanical damage.

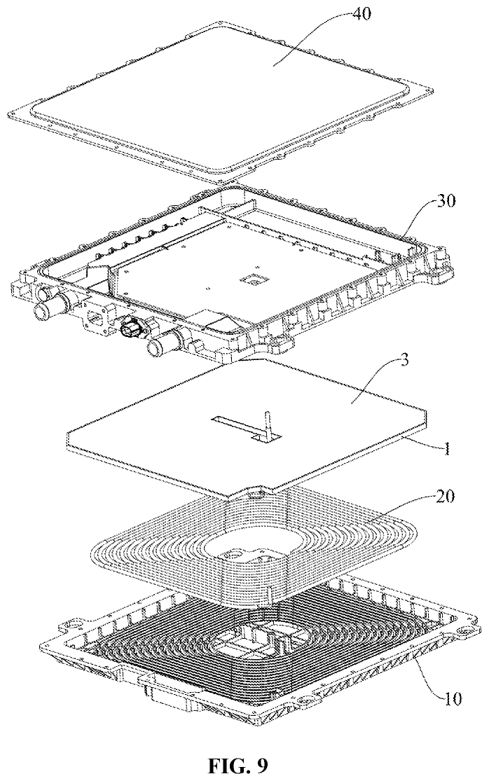

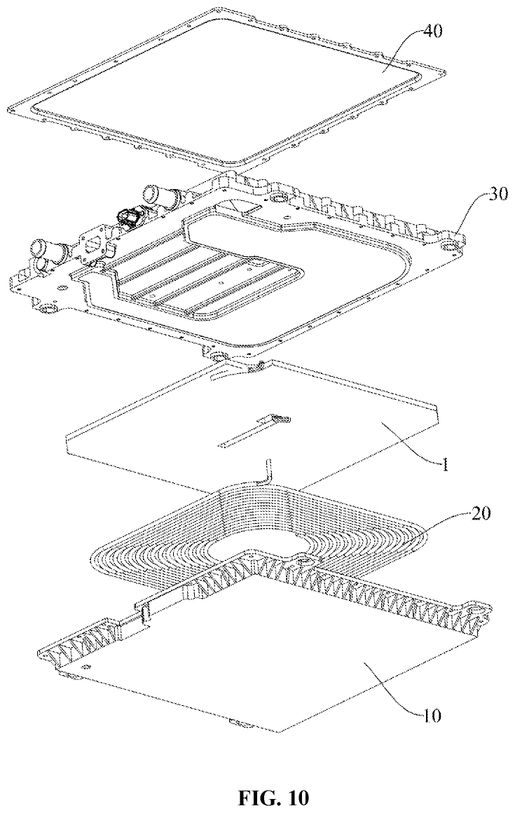

The present utility model further provides a wireless charging apparatus. As shown in FIGS. 8 to 10, the wireless charging apparatus includes a plastic housing 10, a coil assembly 20, a heat dissipation housing 30, a metal upper cover 40 and the preceding shield module for wireless charging. The coil assembly 20 is arranged on the plastic housing 10, the heat dissipation housing 30 is arranged on the coil assembly 20, the shield module for wireless charging is arranged on the side of the heat dissipation housing 30 facing the coil assembly 20, and the metal upper cover 40 is arranged on the heat dissipation housing 30. The coil assembly has two connectors. One of the connectors is located at the center of the coil assembly 20, and the other is located at the edge of the coil assembly 20. The connector located at the center of the coil assembly 20 passes through the through hole 131, and the connector located at the edge of the coil assembly 20 passes through the shield module for wireless charging through the first notch 14. It is to be noted that a control circuit board is installed in the cavity between the heat dissipation housing 30 and the metal upper cover 40. For the specific structure of the control circuit board, reference may be made to the related art, and details will not be repeated herein.

In the wireless charging apparatus provided by the present utility mode, the shield module for wireless charging has a strong capability to resist mechanical damage so that the shielding module for wireless charging has a long service life, thereby enabling the wireless charging apparatus to obtain a longer service life and a better heat transfer effect.

The preceding embodiments illustrate only the basic principles and features of the present utility model. The present utility model is not limited by the preceding embodiments. Various modifications and variations made without departing from the spirit and scope of the present utility model fall within the scope of the present utility model. The scope of the present utility model is defined by the appended claims and their equivalents.

What is claimed is:

1. A shielding module for wireless charging, comprising:
a tray, having a bottom wall and an annular sidewall connected to an edge of the bottom wall, the sidewall and the bottom wall form an accommodation groove therebetween;
a plurality of ferrites, being arranged in the accommodation groove and completely accommodated in the accommodation groove; and
a colloid, being filled in the accommodation groove in a potting manner and filled between the ferrites and the bottom wall, and the tray and the ferrites are integrally formed through the colloid.

2. The shielding module for wireless charging according to claim 1, wherein the bottom wall is provided with a plurality of support blocks on a surface of the bottom wall facing the accommodation groove, the ferrites are supported on the support blocks, and the colloid is arranged to avoid the support blocks.

3. The shielding module for wireless charging according to claim 2, wherein the support blocks are provided, and each of the ferrites is supported on at least one of the support blocks.

4. The shielding module for wireless charging according to claim 3, wherein the support blocks comprise a plurality of first support blocks and a plurality of second support blocks, the first support blocks are arranged in a middle portion of the accommodation groove, and the second support blocks are uniformly spaced at the edge of the bottom wall along a circumferential direction of the tray.

5. The shielding module for wireless charging according to claim 1, further comprising an adhesive film, wherein at least one of top surfaces of the ferrites or bottom surface of the ferrites are adhered to the adhesive film, and the adhesive film is bonded to the colloid.

6. The shielding module for wireless charging according to claim 1, wherein the colloid is filled between the ferrites and the sidewall.

7. The shielding module for wireless charging according to claim 1, wherein a boss is arranged in a middle portion of the tray, the boss is provided with a through hole penetrating an upper side and a lower side of the boss, and the ferrites are directly in contact with the boss or the colloid is filled between the boss and the of ferrites.

8. The shielding module for wireless charging according to claim 1, wherein the colloid is a thermally conductive colloid, and the tray is a thermally conductive plastic.

9. The shielding module for wireless charging according to claim 1, wherein the colloid covers top surfaces of the ferrites, and a top surface of the colloid is flush with a top surface of the tray.

10. The shielding module for wireless charging according to claim 2, further comprising an adhesive film, wherein at least one of top surfaces of the ferrites or bottom surface of the ferrites are adhered to the adhesive film, and the adhesive film is bonded to the colloid.

11. The shielding module for wireless charging according to claim 3, further comprising an adhesive film, wherein at least one of top surfaces of the ferrites or bottom surface of the ferrites are adhered to the adhesive film, and the adhesive film is bonded to the colloid.

12. The shielding module for wireless charging according to claim 4, further comprising an adhesive film, wherein at least one of top surfaces of the ferrites or bottom surface of the ferrites are adhered to the adhesive film, and the adhesive film is bonded to the colloid.

13. The shielding module for wireless charging according to claim 2, wherein the colloid is filled between the ferrites and the sidewall.

14. The shielding module for wireless charging according to claim 3, wherein the colloid is filled between the ferrites and the sidewall.

15. The shielding module for wireless charging according to claim 4, wherein the colloid is filled between the ferrites and the sidewall.

16. The shielding module for wireless charging according to claim 2, wherein a boss is arranged in a middle portion of the tray, the boss is provided with a through hole penetrating an upper side and a lower side of the boss, and the ferrites are directly in contact with the boss or the colloid is filled between the boss and the ferrites.

17. The shielding module for wireless charging according to claim 3, wherein a boss is arranged in a middle portion of the tray, the boss is provided with a through hole penetrating an upper side and a lower side of the boss, and the ferrites are directly in contact with the boss or the colloid is filled between the boss and the ferrites.

18. The shielding module for wireless charging according to claim 4, wherein a boss is arranged in a middle portion of the tray, the boss is provided with a through hole penetrating an upper side and a lower side of the boss, and the ferrites are directly in contact with the boss or the colloid is filled between the boss and the ferrites.

19. The shielding module for wireless charging according to claim 2, wherein the colloid is a thermally conductive colloid, and the tray is a thermally conductive plastic.

20. A wireless charging apparatus, comprising a plastic housing, a coil assembly arranged on the plastic housing, a heat dissipation housing arranged on the coil assembly, a metal upper cover arranged on the heat dissipation housing and a shield module for wireless charging according to claim 1, wherein the shield module for wireless charging is arranged on a side of the heat dissipation housing facing the coil assembly.
